(19) United States
(12) Patent Application Publication
(10) Pub. No.: US 2013/0250471 A1
(43) Pub. Date: Sep. 26, 2013

(54) COMPRESSIBLE CONDUCTIVE ELEMENT FOR USE IN CURRENT-CARRYING STRUCTURE

(71) Applicant: COMPONENT RE-ENGINEERING COMPANY, INC., Santa Clara, CA (US)

(72) Inventor: Dennis George REX, Sunnyvale, CA (US)

(73) Assignee: COMPONENT RE-ENGINEERING COMPANY, INC., Santa Clara, CA (US)

(21) Appl. No.: 13/797,467

(22) Filed: Mar. 12, 2013

Related U.S. Application Data
(60) Provisional application No. 61/614,415, filed on Mar. 22, 2012.

(51) Int. Cl. H01L 21/683; H01L 21/67

(52) U.S. Cl. CPC H01L 21/6833; H01L 21/67103
USPC 361/234; 174/126.1; 219/444.1

(57) ABSTRACT

An electrostatic chuck is provided and can include a body having a surface for receiving a wafer. An electrode can be embedded in the body and spaced beneath the surface by a layer. A compressible element having a first end portion electrically coupled to the electrode and a second end portion coupleable to the electrical connector can be provided to inhibit damage to the exposed portion of the electrode and the layer during use. Other embodiments of an electrostatic chuck and embodiments of a conductive element are provided, and an embodiment of a wafer heater is provided.

### CROSS REFERENCE TO RELATED APPLICATION

The application claims priority to U.S. provisional application Ser. No. 61/614,415 filed Mar. 22, 2012, the entire content of each of which is incorporated herein by this reference.

### FIELD OF THE INVENTION

The present invention relates to current-carrying structures and more particularly to current-carrying structures subject to high temperatures.

### BACKGROUND

Current-carrying structures have been provided, for example in an electrostatic chuck formed from ceramic and having a wafer-receiving surface and an embedded electrode underlying such surface by a thin layer of the chuck. Access to the electrode is provided through a port extending through the underside of the chuck.

A common method for establishing electrical connection to the electrode involves placement of all or a portion of a metal pin in the port and attachment of the metal pin, using solder or a conductive adhesive, to the underside of the electrode. After such attachment, the access hole is filled with a suitable potting or encapsulating compound to isolate the thin layer of the chuck from external stresses transmitted through the electrical connection. However, owing to the significantly different thermal expansion coefficients of the assembly, that is the assembly of the chuck body, the metal connection pin and the potting compound, the thin layer of the chuck has remained a chronic source of failure.

Other current-carrying structures such as conductors in a wafer heater have been provided. Such electrical conductors can extend from a heating element in a disk that receives a wafer through a hollow shaft and through the chamber mount of the heater to a power source external of the wafer heater. In the case of a wafer heater made from aluminum and conductors made from nickel, the shaft can have a greater coefficient of thermal expansion than the nickel conductors and can exert tension on the conductors that in turn must be resisted by the connection of the conductors to the heating element. In the case of a wafer heater made from aluminum nitride or another ceramic material, the nickel conductors can have a greater coefficient of thermal expansion than the shaft, placing the connections between the conductors and the heating element under compression. These tensile and compressive forces on the conductors, and points of connection, may be significant causes of failure in normal operation, resulting in broken connections or actual buckling deformation of the conductors.

Several solutions are extant in the industry. One solution is to interpose a section of nickel wire cable in the conductor. Unfortunately, in order to have sufficient current carrying capacity, that is ampacity, such a nickel wire cable is typically quite stiff in practice. Another solution is to interpose a section of straight or convoluted nickel strip in the conductor. However, many conductors in wafer heaters are required to carry high frequency current and since the flow of radio frequency current concentrates at the surface of a conductor as its frequency increases, known as the skin effect, such a strip is often a poor radio frequency conductor as it has insufficient surface to accommodate the required radio frequency currents of a wafer heater.

What is needed is a flexible method of connection that is capable of significantly improved stress isolation for use in a current-carrying structure.

### BRIEF DESCRIPTION OF THE DRAWINGS

FIG. 1 is an isometric view of a portion of an electrostatic chuck for use in a semiconductor manufacturing process having one embodiment of a current-carrying structure.

FIG. 2 is a cross-sectional view of the electrostatic chuck of FIG. 1 take along the line 2-2 of FIG. 1.

FIG. 3 is an isometric view of one embodiment of the electrostatic chuck of the present invention with an electrical connector coupled to the chuck.

FIG. 4 is a cross-sectional view of the electrostatic chuck and electrical connector of FIG. 3 taken along the line 4-4 of FIG. 3 but with the conductive element shown in plan.

FIG. 5 is an enlarged cross-sectional view of a portion of the electrostatic chuck and electrical connector of FIG. 3, with a portion of the conductive element cut away, taken along the line 5-5 of FIG. 4.

FIG. 6 is a cross-sectional view of a wafer heater for use in a semiconductor manufacturing process having another embodiment of a current-carrying structure.

FIG. 7 is an enlarged view of a portion of the wafer heater of FIG. 6, taken along the line 7-7 of FIG. 6 and partially cut away.

### DETAILED DESCRIPTION OF THE INVENTION

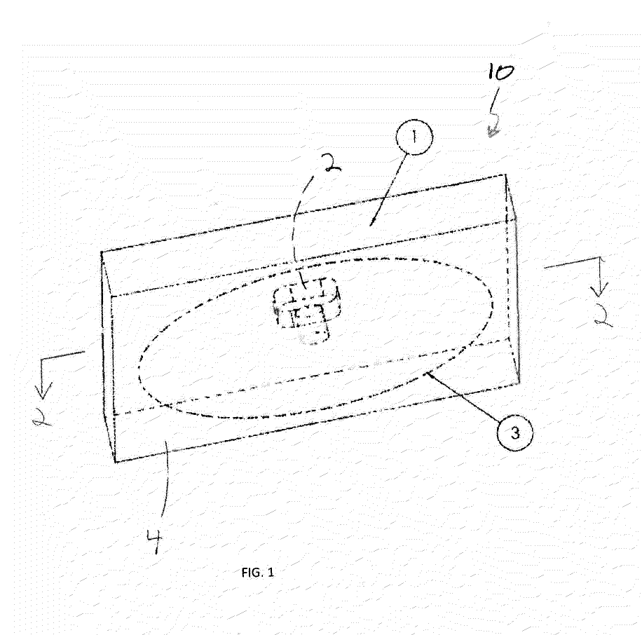

FIG. 1 is a schematic view of a portion of an electrostatic chuck 10 fabricated from any suitable dielectric material common to the art, for example aluminum nitride or alumina or another ceramic. The drawings herein are schematic and the relative size between structural elements or features described in the drawings are not necessarily to scale. The chuck includes a body 1 and an integral conductive electrode 3 underlying a chuck surface 4 on which a wafer being processed rests. In some embodiments, the conductive electrode can have a thickness ranging from 0.0005 to 0.0010 inch. It is appreciated that an electrostatic chuck can be provided with one or more conductive electrodes. For example, in one embodiment a single conductive electrode extends substantially across the entire diameter or transverse dimension of the chuck. In another embodiment, two semicircular conductive electrodes can be provided. In another embodiment, a plurality of two or more conductive electrodes can be provided in a variety of shapes and sizes which in the aggregate substantially approximate the shape and size of the chuck surface 4.

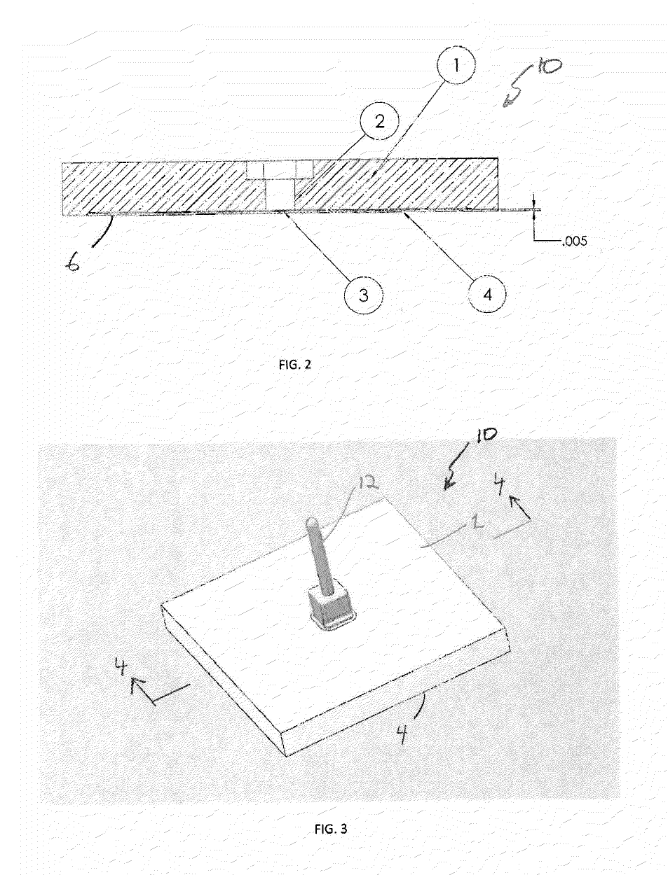

Looking at a cross-section of the chuck in FIG. 2, the conductive electrostatic electrode 3 is disposed in very close proximity to the wafer surface 4, that is the surface to which the wafer is electrostatically held for the purpose of subsequent processing such as lithography, deposition, etch, or ion implant. It is advantageous to have the chucking electrode close to the wafer surface 4 to maximize the capacitance between the electrode and the wafer and, as a result, maximize the chucking force, that is the attraction of the wafer to the chucking electrode 3. The thickness of the dielectric layer or web 6 between the chucking electrode 3 and the wafer surface 4 can be of any suitable dimension. For example, a layer 6 having a thickness of 0.005 inch is typical of practical electrostatic chuck embodiments. It is customary to provide access to the underside of the electrostatic electrode 3 through the underside of the dielectric body 1 for the purpose of making electrical contact with the electrode 3. Such access, represented here as feature 2, can be any suitable hole, bore, aperture, opening, access port or volume. In one embodiment, the aperture or hole 2 has a diameter of approximately 0.070 inch. It is appreciated that the resulting chuck structure or layer 6 extending between the chuck surface 4 and the electrode 3 proximate to the electrical connection, for example a 0.005 inch layer or web 6 of ceramic material, is extremely fragile and subject to fracture and dielectric failure, both during manufacture of the chuck and during use of the chuck.

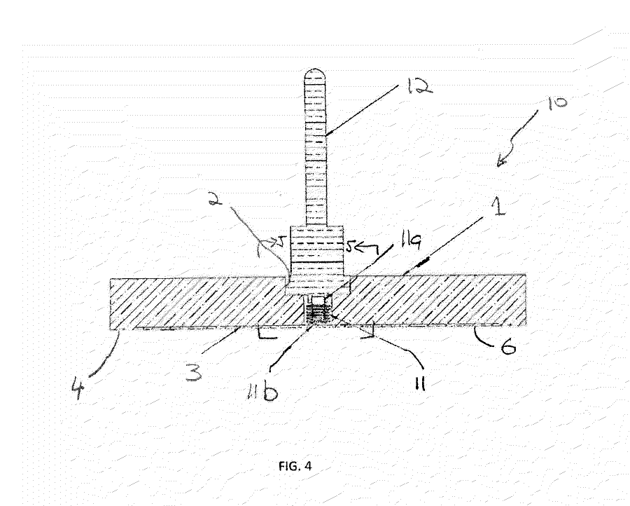

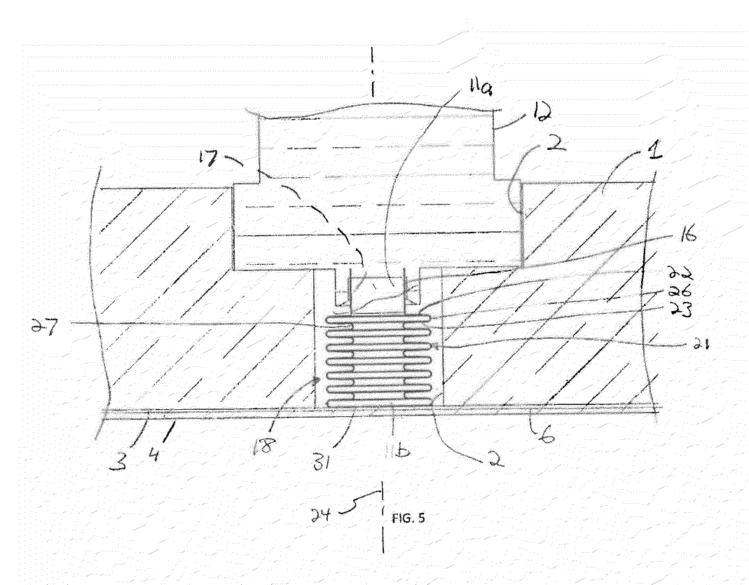

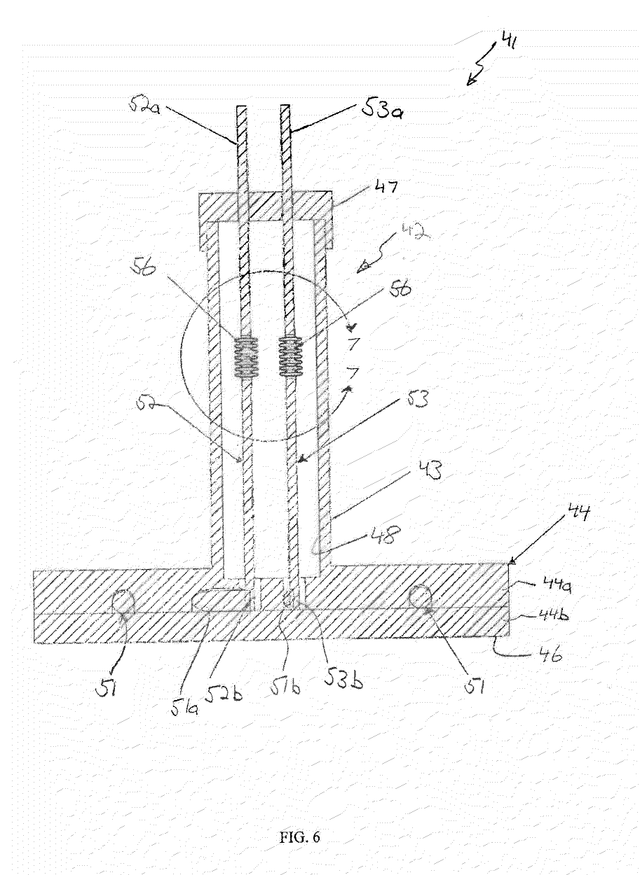

In one embodiment of the invention, a flexible or conductive element 11, which can be referred to as a compressible or expandable element or a spring element, is provided for making electrical contact with the electrode 3 of electrostatic chuck 10 (see FIGS. 4-5). Some or all of the element 11 can be disposed in the aperture or hole 2 of the chuck body 1. In one embodiment, the element 11 is sized and shaped for placement entirely within the hole 2. The element 11 can be directly coupled or connected to the electrode 3, or indirectly coupled or connected to the electrode by an intermediate element (not shown). In embodiment, the element has a first end 11a connected to a conventional electrical terminal 12 and an opposite second end 11b directly connected to the electrode 3. The electrode 3 in combination with the electrical terminal can be referred to as a current-carrying structure.

In one embodiment, the flexible or compressible element 11 is formed from a hollow cylindrical thin-walled body 16 that is provided with an internal cavity 17 and that includes a bellows portion or bellows 18. In one embodiment, shown in FIGS. 4 and 5, the first end portion or end 11a. of the element is tubular for electrically joining by any suitable means, such as solder or a conductive paste or epoxy, to the electrical terminal 12. The compressible element 11 can be made from any suitable conductive material(s) such as nickel that is gold plated so as to be corrosive resistant and suitable for use with solder when electrically connecting to other elements, such as the electrical terminal 12 and the electrode 3. In one embodiment, the thin-walled body 16 of the compressible element 11 has a thickness ranging from 0.0005 to 0.0020 inch, although thicknesses outside of this range are permissible.

In one embodiment, the bellows portion 18 is comprised of at least one flexible element 21 and in one embodiment a plurality of spaced-apart flexible elements 21 arranged transversely of the longitudinal axis 24 of the body 16. In one embodiment, each of the one or more flexible elements is formed from a first or top wall 22 and a second or bottom wall 23 that in one embodiment can each be planar and extend substantially perpendicular to the longitudinal axis 24 of the body 16. The circular outer periphery of the walls 22 and 23 can be joined together by a circular outer wall 26 that can be semi-circular in cross section so as to provide the flexible element 21 with a rounded outer periphery. The circular inner periphery of the bottom wall 23 of one flexible element 21 and the top wall of the adjoining flexible element 21 can be joined together by a circular inner wall 27 that can be semi-circular in cross section. In this manner, the outer wall of the bellows portion 18 has a serpentine configuration when viewed in plan from the side, as shown in FIGS. 4-5. In one embodiment, the bottom of the compressible element 11 is formed from a planar bottom wall 31, which wall 31 can be the bottom-most wall of the bellows portion 18 and in this regard can be the bottom wall 23 of the bottom flexible element 21 of the bellows 18. In one embodiment, the bottom wall 31 of the element can have a diameter and area approximating the diameter and area of the exposed portion of the electrode 3 at the base of aperture or access port 2, and in one embodiment the diameter of the bottom wall 31 is substantially equal to the diameter of the flexible elements 21 and thus bellows portion 18.

Although it is appreciated that the compressible element 11 can be of any suitable size, in one embodiment the compressible element 11 can have a height of approximately 0.075 inch, and top end portion or end 11a can have an external diameter of approximately 0.028 inch. The bellows portion 18 can have a height of approximately 0.050 inch. Each of the flexible elements 21 can have an outer diameter at outer wall 26 of approximately 0.055 inch, an inner diameter at the outside of inner wall 27 of approximately 0.026 inch and a distance between the top of first wall 22 and the bottom of second wall 23 of approximately 0.004 inch. In one embodiment, the bellows portion 18 is sized and shaped for placement entirely within the access port or hole 2. In one embodiment, the compressible element has a k or spring value of 0.2 grams per millimeter, and the bellows portion 18 and the flexible elements 21 thereof are compressible along the longitudinal axis 24 of the element 11 a distance of as much as 0.020 inch. In one embodiment, the compressible element is installed so that the bellows portion 18 is compressed 0.005 inch from its free length, or uncompressed state, during installation to allow the bellows portion, and thus the compressible element 11, to be in a “dynamic range” wherein it may extend or compress with relatively equal k values.

The body 16 can be formed or made in any suitable manner and in one embodiment is electroformed. For example, the nickel or other base material of the body 16 can be plated onto a conductive mandrel, which can be made from aluminum or any other suitable material. After formation, the mandrel can be dissolved in a suitable known process using acid or another suitable corrosive material. The optional gold layer is plated onto the nickel base layer of the body 16, either before or after dissolution of the mandrel.

The compressible element 11 can be secured to the electrical connector 12 and to the electrode 3 by any suitable manner such as solder or a conductive adhesive or epoxy. In one embodiment, the top end portion 11a of the element 11 can be joined to the bottom of the connector 12 by means of soldering, and the electrical connector 12 may be glued or potted to the ceramic electrostatic chuck body 1. The bottom end portion 11b of the element 11 can be joined to the exposed surface of the electrode 3 within hole 2 by solder. Solder connections to the compressible element 11 provide a strong electrical connection between the element 11 and the adjoined connector 12 and electrode 3.

The relatively large planar bottom wall 31 of the element 11 serves to provide a large connection surface between the compressible element 11 and the electrode 3. The diameter of bottom wall 31 closely approximates the diameter of the bottom of aperture or hole 2 and thus the diameter of the portion of the electrode 3 exposed by the hole 2. The relatively large contact or engagement area of the bottom wall 31 of the bellows portion 18 with the chuck electrode 3 provides a relatively large support structure and surface for the relatively thin portion of the electrode 3 and the underlying layer 6 exposed at the bottom of aperture 2.

In operation and use, the stress that may be transmitted to the thin ceramic web or layer 6 from either the electrical connector 12 or from dissimilar expansion caused by intervening potting materials serving to join the connector 12 to the chuck body 1 in the access annulus 2, or from the dissimilar expansion between the access annulus 2 and the compressible element 11, is reduced or minimized. In addition, the relatively large contact area between the compressible element 11 and the electrode, provided by the relatively large-diameter bottom wall 31 of the bellows portion 18 that approximates the exposed surface and area of the electrode 3 at the bottom of aperture or access annulus 2, inhibits the formation of concentrated loads in the relatively thin laminate structure formed by the electrode 3 and the layer 6 by, among other things, providing structural support to such thin laminate structure, distributing any axial load provided by the compressible element 11 evenly across such laminate structure or a combination of the foregoing.

It is appreciated that other embodiments of the compressible element 11 of the present invention can be provided. For example, the compressible element 11 can include a suitable spring such as a spiral spring (not shown), either separate from bellows portion 18 and thus alone or in combination with bellows portion 18 or another compressible structure. Such a spring can be made from any suitable conductive material such as beryllium copper. The spring can be joined at a first end to the electrical connector 12 and at a second end to the electrode 3, either directly or indirectly, by any suitable means such as a conductor paste or epoxy or solder.

It is additionally appreciated that the invention may have applications beyond electrostatic chucks. For example, a compressible element of the invention similar to element 11 or otherwise can be provided in any current-carrying structure. In one embodiment, the current-carrying structure can be a wire or cable, and a compressible element of a suitable type, for example as disclosed herein and including for example a bellows portion similar to bellows portion 18, can be spliced into or formed as part of the current-carrying structure. In one embodiment, the compressible element can join together first and second portions of the current-carrying structure. Such compressible element can be open at both ends, for example bottom wall 31 of the bellows portion can be removed or an opening can otherwise be provided in the base of the bellows portion of such compressible element. In one embodiment, the current-carrying structure can include a portion with a substantially planar surface, such as an electrode similar to electrode 3 having a planar surface, and the bellows or compressible portion of the compressible element can be joined to such planar surface of the portion in any suitable manner, for example as discussed above. In each instance, the compressible element can serve to reduce stress concentrations due to disparate coefficients of thermal materials in the first and second portions of the current-carrying structure, the surrounding or related structure, or both.

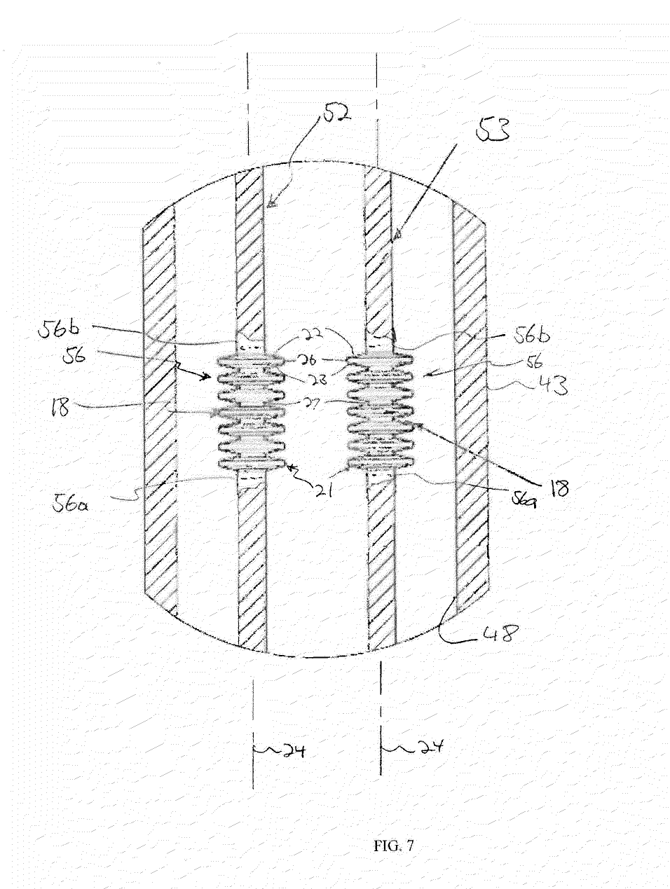

One embodiment of a current-carrying structure is illustrated in FIGS. 6-7. Wafer heater 41 therein includes a body 42 that can be formed from one or more elements. In one embodiment, body 42 includes a hollow shaft 43 formed integral with at least part of a chuck or disk 44, such as a first or bottom portion 44a of the disk. The disk 44 includes a second or top portion 44b, which is secured to the bottom portion 44a in any suitable manner and has a top planar surface 46 for receiving a wafer (not shown) to be treated. A chamber mount 47 is included in body 42 of the wafer heater at the base of the shaft 43 and a suitable seal (not shown), such as an O-ring, can be provided between the chamber mount 47 and the shaft 43 to provide a hermetic seal between the chamber mount and the shaft 43 and another suitable seal (not shown), such as an O-ring, can be provided between the chamber mount 47 and the bottom of the process chamber (not shown) to provide a hermetic seal between the chamber mount and the chamber. Such seals serve to inhibit process gas from leaking outside the chamber, either via the interior or central passageway 48 of the shaft 43 or directly, and in this manner the wafer heater 41 is a hermetic assembly.

An embedded heating element 51 is included in disk 44, for example between the top portion 44b and the bottom portion 44a of the disk 44. The heating element can be of any conventional type, and in one embodiment can be a circular ring made from any suitable resistive material such as metal which underlies at least a portion of the disk surface 46. The heating or heater element 51 can have a first end portion 51a, for example near the central portion of the disk 44, which is electrically coupled to a first current-carrying structure or conductor 52 and a second end portion 51b, for example near the central portion of a second current-carrying structure or conductor 53, which is electrically coupled to a second conductor 53. Each of the conductors can extend through the interior or central passageway or bore 48 of the shaft and through respective bores in the chamber mount so as to have respective first end portions 52a, 53a accessible exterior or outside the wafer heater 41 for the purpose of external connection to a power supply (not shown). The first and second conductors 52,53 have respective second end portions 52b, 53b electrically coupled or secured to respective first and second end portions 51a, 51b of the heating element 51 by any suitable means such as brazing. In practice, the conductors 52 and 53 can be fixed to the chamber mount 47 so that external forces created by handling, shipping, or simply making electrical connection to the conductors are not transmitted through the conductors to the point of attachment of the conductors, that is second end portions 52b and 53b, to the heating element 51.

The wafer heater 41, including shall 43, disk 44 and chamber mount 47 thereof, can be fabricated from the same material, for the purpose of making a unitized assembly, or from different materials. Although any suitable materials can be used, particularly suitable materials are compatible with typical gasses, such as fluorine, used in semiconductor manufacturing processes. In one embodiment, the entire wafer heater 41 can be made from aluminum. In another embodiment, the chamber mount 47 can be made from a suitable metal and the remainder of the wafer heater 41 can be made from a suitable ceramic such as aluminum nitride. The conductors 52 and 53 can be made from any suitable electrically conductive material, and in one embodiment are fabricated from a material, such as nickel, that is resistive to oxidation in air at the elevated temperatures at which wafer heaters operate. The material of the conductors 52 and 53 typically has a coefficient of thermal expansion that is different than the coefficient of thermal expansion of the materials of the shaft 42, disk 44 and chamber mount 47.

In one embodiment of the invention, a flexible element 56, which can be referred to as a compressible or expandable element or a spring element, is interposed or provided in each of the first and second conductors 52 and 53 in interior 48 of the shaft 43 (see FIGS. 6-7). The element 56 can be directly coupled or connected to the conductor, or indirectly coupled or connected to the conductor. In one embodiment, each of the compressible elements has a first end 56a directly connected to the upper portion of the respective conductor 52 or 53 and an opposite second end 56b directly connected to the lower portion of the respective conductor 52 or 53.

In one embodiment, each of the compressible or conductive elements 56 is substantially similar to compressible element 11 described above and like reference numerals have been used to describe like components of compressible elements 56 and 11. In that regard, each of the compressible elements 56 is formed from a hollow cylindrical thin-walled body 16 that is provided with an internal cavity 17 and that includes a bellows portion or bellows 18. In one embodiment, shown in FIGS. 6 and 7, the first end portion or end 56a of each element is tubular for electrically joining by any suitable means, such as solder or brazing, to the upper portion of the respective conductor 52 or 53, and the second end portion or end 56b of each element is tubular for electrically joining by any suitable means, such as solder or brazing, to the lower portion of the respective conductor 52 or 53. In one embodiment, the internal bore of each end portion 56a and 56b is approximately equal to the external diameter of the respective conductor 52 or 53 and the upper and lower portions of the conductor seat within the respective end portion 56a and 56b of the compressible element 56. In one embodiment, the thin-walled body 16 of the compressible element 56 has a thickness ranging from 0.002 to 0.025 inch, although thicknesses outside of this range are permissible. Relatively large thicknesses of the compressible elements 56 can be required when relatively large currents are required to be carried by the compressible elements. For example, a thickness of approximately 0.012 inch would accommodate a current of approximately 20 amperes to be carried by the compressible element.

In one embodiment, the bellows portion 18 is comprised of a plurality of spaced-apart flexible elements 21 arranged transversely of the longitudinal axis 24 of the body 16. In one embodiment, each of the flexible elements 21 is formed from a first or top wall 22 and a second or bottom wall 23 that in one embodiment can each be planar and extend substantially perpendicular to the longitudinal axis 24 of the body 16. The circular outer periphery of the walls 22 and 23 can be joined together by a circular outer wall 26 that can be semi-circular in cross section so as to provide the flexible element 21 with a rounded outer periphery. The circular inner periphery of the bottom wall 23 of one flexible element 21 and the top wall of the adjoining flexible element 21 can be joined together by a circular inner wall 27 that can be semi-circular in cross section. In this manner, the outer wall of the bellows portion 18 has a serpentine configuration when viewed in plan from the side, as shown in FIGS. 6-7.

Although it is appreciated that the compressible element 56 can be of any suitable size, in one embodiment the compressible element 56 can have a height of approximately one inch, and each of top end portion or end 56a and bottom end portion or end 56b can have an external diameter of approximately 0.155 inch. The bellows portion 18 can have a height of approximately 0.60 inch. Each of the flexible elements 21 can have an outer diameter at outer wall 26 of approximately 0.5 inch, an inner diameter at the outside of inner wall 27 of approximately 0.2 inch and a distance between the top of first wall 22 and the bottom of second wall 23 of approximately 0.1 inch. In one embodiment, the compressible element 56 can have a k or spring value ranging from 500 to 3000 grams per millimeter, and the bellows portion 18 and the flexible elements 21 thereof are compressible along the longitudinal axis 24 of the element 56 a distance of as much as 0.13 inch. In one embodiment, each of the compressible elements is installed so that the bellows portion 18 is compressed 0.04 inch from its free length, or uncompressed state, during installation to allow the bellows portion, and thus the compressible element 56, to be in a “dynamic range” wherein it may extend or compress with relatively equal k values.

The compressible elements 56 can be made from any suitable conductive material such as any of the materials discussed above with respect to compressible element 11. The compressible elements 56 can be made in any suitable manner, for example as discussed above with respect to compressible element 11, and in one embodiment is hydroformed. In one suitable hydroforming procedure, a simple cylinder of the desired material of the compressible element, such as nickel, is expanded by high pressure fluid to conform the cylinder to the inside of a suitable die utilized to shape the exterior of the compressible element. After such formation, the die can be split to permit removal of the now-formed compressible element. Another suitable method for manufacturing the compressible elements 56 is welding. In one embodiment of such a welding procedure, adjacent top and bottom walls 22, 23 of the bellows 18 are welded together at circular outer wall 26 and at circular inner wall 27 to create the hermetic convolutions of the bellows 18. As part of any of such manufacturing techniques, the nickel formation material of the compressible element 56 can be plated, for example with gold, in the manner and for the reasons discussed above.

In operation, the temperature of the wafer heater 41 and body 42 thereof may be between 400° C. and 800° C., depending upon the process and the materials of construction. Wafer heaters made from aluminum often operate to temperatures of approximately 500° C., while wafer heaters made from aluminum nitride often operate to temperatures of approximately 800° C.

The compressible element 56 interposed in each of the metal conductors 52 and 53 can accommodate the dissimilar expansion of the assembly of the body 42 and conductors 52 and 53, for example as a result of the disparate coefficients of thermal expansion of the materials of the body 42 and the material of the conductors 52 and 53, while at the same time providing a generous surface area for radio frequency current as appropriate to the process. The invention discloses the use of a flexible metal bellows 18, which can be fabricated from nickel for both oxidation resistance and ease of joining to nickel conductors 52 and 53. The bellows 18 can have a diameter that is larger than the diameter of the respective conductor 52 or 53 and thus provide greater surface area, and therefore good radio frequency current conductivity, than that of the conductor 52 or 53 itself, while offering extraordinary axial flexibility to the conductor assembly.

I claim:

1. An electrostatic chuck for use with a wafer and an electrical connector, comprising a body having a surface adapted for receiving the wafer, an electrode embedded in the body and spaced beneath the surface by a layer of the body, an access port in the body exposing a portion of the electrode, the exposed portion of the electrode and the layer being relatively thin and fragile, and a compressible element having a first end portion electrically coupled to the electrode and a second end portion coupleable to the electrical connector whereby the compressibility of the compressible element during use inhibits damage to the exposed portion of the electrode and the layer.

2. The electrostatic chuck of claim 1, wherein the compressible element has a bellows portion.

3. The electrostatic chuck of claim 2, wherein the exposed portion of the electrode has an area and wherein the bellows portion has a planar surface with a cross-sectional area approximating the area of the exposed portion of the electrode for inhibiting the formation of concentrated loads to the exposed portion of the electrode and the layer.

4. An electrostatic chuck for use with a wafer and an electrical connector, comprising a body having a surface adapted for receiving the wafer, an electrode embedded in the body and spaced beneath the surface by a layer of the body, an access port in the body exposing a portion of the electrode having an area, the exposed portion of the electrode and the layer being relatively thin and fragile, and a conductive element having a first end portion provided with a planar surface with a cross-sectional area approximating the area of the exposed electrode that is electrically coupled to the electrode and a second end portion coupleable to the electrical connector whereby the planar surface provides structural support to the exposed portion of the electrode and the layer.

5. The electrostatic chuck of claim 4, wherein the conductive element extends along a longitudinal axis and includes at least one flexible element that is compressible along the longitudinal axis.

6. A conductive element for use with a wafer and an electrostatic chuck having a surface for receiving the wafer and an electrode embedded in the chuck and spaced beneath the surface by a layer of the chuck and an access port in the chuck exposing a portion of the electrode which together with the layer is relatively thin and fragile, comprising a hollow body of a conductive material that extends along a longitudinal axis, the body including a bellows portion adapted for electrical coupling to the portion of the electrode, the bellows portion being sized and shaped for placement in the access port and being compressible along the longitudinal axis.

7. The conductive element of claim 6, wherein the bellows portion includes a plurality of flexible elements that are compressible along the longitudinal axis.

8. The conductive element of claim 6, wherein the exposed portion of the electrode has an area and wherein the bellows portion has a planar surface with a cross-sectional area approximating the area of the exposed portion of the electrode for providing structural support to the exposed portion of the electrode and the layer.

9. A wafer heater for use with a wafer, comprising a disk having a surface adapted for receiving the wafer, a heating element embedded in the disk and having first and second ends, a chamber mount and a shaft extending between the disk and the chamber mount and being provided with an internal passageway, first and second conductors extending through the chamber mount and the internal passageway of the shaft and electrically coupled respectively to the first and second ends of the heater element, the first and second conductors having a coefficient of thermal expansion and the disk, the shaft and the chamber mount each having a coefficient of thermal expansion different than the coefficient of thermal expansion of the first and second conductors, each of the first and second conductors including a compressible portion for inhibiting damage to the first and second conductors from disparate coefficients of thermal expansion during operation of the wafer heater.

10. The wafer heater of claim 9, wherein the compressible element has a bellows portion.

11. A conductive element for use in a current-carrying structure having a first portion and a second portion, comprising a hollow body of a conductive material adapted to couple the first portion to the second portion, the hollow body extending along a longitudinal axis and including a bellows portion that is compressible along the longitudinal axis for accommodating stresses experienced by the current-carrying structure.

12. The conductive element of claim 11, wherein the bellows portion includes a plurality of flexible elements that are compressible along the longitudinal axis.

13. The conductive element of claim 11, wherein the current-carrying structure is a conductor in a wafer heater, the conductor having a first portion and a second portion.

14. The conductive element of claim 11, wherein the first portion of the current-carrying structure is an electrode in an electrostatic chuck and the second portion of the current-carrying structure is an electrical connector.
